(19) United States
(12) Patent Application Publication
(10) Pub. No.: US 2018/0033937 A1
(43) Pub. Date: Feb. 1, 2018

(54) THERMOELECTRIC ENERGY HARVESTING FROM PAVEMENT STRUCTURE

(71) Applicant: CASE WESTERN RESERVE UNIVERSITY, CLEVELAND, OH (US)

(72) Inventors: Xiong Yu, Beachwood, OH (US); Guangxi Wu, Solon, OH (US)

(21) Appl. No.: 15/661,337

(22) Filed: Jul. 27, 2017

Related U.S. Application Data
(60) Provisional application No. 62/367,334, filed on Jul. 27, 2016.

(51) Int. Cl. H01L 35/02; H01L 35/20; H01L 35/30

(52) U.S. Cl. CPC H01L 35/02; H01L 35/30; H01L 35/20

(57) ABSTRACT

Electrically parallel thermoelectric modules (TEMs), especially induced multilayered TEMs, have the potential to stimulate the applications of TEMs to harvest energy from naturally existing temperature gradients, because of the convenience and cost-effectiveness to fabricate large area devices. A thermoelectric-based system comprises a thermoelectric module comprising an upper surface and a lower surface, said upper surface being separated from said lower surface by a “n” type material, or a “p” type material, or both; a thermally conductive plate, being located beneath said thermoelectric module, said plate being capable of transferring heat from said thermoelectric module lower surface via a thermally conductive leg to a heat sink, and said system capable of being located in a pavement having a temperature gradient and being capable of generating electricity therefrom.

### FIELD OF THE INVENTION

The present invention relates to various thermoelectric-based energy harvesting systems that utilize inherent heat sources such as pavement to produce electricity. Such electricity can be used to power smart features on and beside pavement (monitoring sensor, smart traffic lane indicators, infrastructure to vehicle communication devices, etc). When stored, it can also be used to charge batteries. The source of energy is the inherent heat produced by absorption of solar energy by road surface (particularly high for pavement with dark surface such as asphalt road). The energy will be converted to electricity by thermoelectric or pyroelectricity.

To further improve the cost effectiveness of energy harvesting system, pavement design can be improved by utilizing a layer having high thermal conductivity to collect in a large area a concentrate heat source, so that each energy conversion unit can cover a large area and therefore save the cost of energy harvesting system needed.

A thermoelectric modular is a device having an upper and lower surface wherein the surfaces are separated an “n” type or a “p” type thermoelectric material, or both, which produce electricity when there are differential temperatures on the upper and lower surfaces. Pyroelectricity is produced when there are time dependent variations of the temperature. Both can be complementary to each other in providing electricity conversion.

The use of flexible materials or other structures, to accommodate the deflection of road under service traffic load, which otherwise will damage the conventional thermoelectric device, ensures that the system is durable, abates damage and extends the life thereof.

The present invention also relates to thermoelectric units that function as a current source, and that have much higher robustness and efficiency under operation conditions to use the heat inherent in a pavement.

The system can be optimized with computational model analyses to ensure maximum efficiency in electricity production.

### BACKGROUND OF THE INVENTION

Future highway systems will be smart, green, resilient, and sustainable. The distributed nature of highway systems make it difficult to supply conventional energy to the operation of components that support the next generation of highway systems, such as electrical vehicle chargers, sensors, communications (V2V, V2I), and other applications. This innovative technology will turn highway into distributed energy generators by utilizing the thermal energy embedded in the road structure.

The new technology harvests the thermal energy from pavement structure. The uniqueness include: 1) architecture of thermoelectric generators to ensure high efficiency, 2) multifunctional road design with integration of thermal conductive layer for thermal energy collection and therefore improve its cost effectiveness, and 3) design of flexible thermoelectric component by 3D printing. Preliminary analyses shows the potential of over 1 watts/m̂2 electricity production from thermoelectricity. The performance will be further improved with optimizing system design.

Energy shortages and environmental degradation have become two of the most critical current issues. The world's escalating demand for energy accelerates the combustion of fossil fuels, because of the lack of alternative energy resources, which further deteriorates the environment by means of global warming, greenhouse gas emission, climate change, ozone layer depletion, acid rain, etc. Renewable energy harvesting techniques, such as thermoelectric (TE) technology, have received extensive attention, driven by their potential to mitigate both the energy and environmental crises. The energy consumption by the U.S. in 2014 is about 10 Trillion kWh and predicted to continue increasing annually. More than half of the primary energy utilized is wasted in form of heat and given off by power stations, heating systems, plants, vehicles, etc. Thermoelectric module (TEM) used as power generator (TEG) can directly convert waste heat, as well as heat from solar, biomass, and earth sources into electricity, which makes TE technology even more attractive than other types of renewable energy harvesting techniques.

TE technology possesses advantages such as gas-free emissions, vast scalability, maintenance-free operation without any moving parts and chemical reactions, no damage to the environment during operation, and solid-state operation which leads to a long life span. However, its disadvantages of low energy-conversion efficiency and corresponding high material and fabrication cost have become the bottleneck that limits its development and implementation.

As a result, massive research has been carried out from various aspects, including analytical and numerical analysis of TEM performances, TE material development, TEM device structure design, TEG application, etc.

Literature Review of TE Research

Analytical and Numerical Analysis of TEM Performance

Design and optimization of TEM relies on precise modeling of its fundamental working principles and energy-conversion mechanisms. Researchers have made much effort in modeling the behaviors and performances of TE devices by solving governing equations analytically. Temperature dependency of material properties and the induced Thomson effect and are usually neglected in order for people to get qualitative analog solutions. More precise modeling processes have also been proposed by including temperature dependency of material properties and the Thomson effect. However, the shortcomings of the analytical method limit its potential in modeling TE devices. The computational complexity makes this method time consuming and easy to induce errors. Most calculations are limited to one dimensional for simplicity. The visualization of the calculation results is not straightforward.

Electrical analogy method appeals to many researchers because the mature knowledge in the area of electric circuits can be utilized in the thermal field analysis. It also makes it possible to couple the thermal field and electric field in the same simulation environment, such as the finite difference software SPICE (Simulation Program with Integrated Circuit Emphasis), which is widely used in the area of circuit analysis. Even though this method is powerful for simulating complicated load electric circuits of TEGs, the disadvantages impact its popularity. The electrical abstraction of the thermoelectric device overly emphasizes lumped properties of the TEM, such as the output power, temperature difference between the two ends, etc. Parameter distributions (especially three dimensional distributions) inside the TEM are not convenient to be visualized. This method lacks the sensitivity of the module size influence on the TEM performance, which causes difficulties for researchers to optimize the shape of the TEM. In order to increase the visualization ability of the electrical analogy method, a three dimensional TCAD (Synopsys Technology Computer Aided Design) implementation has been carried out. However, the governing equations and the working performances of the TEM are not fully verified.

As commercial finite element multi-physics simulation software quickly improves, researchers are attracted to model TEM performances numerically using finite element method (FEM). Thomson effects and temperature dependency of the TEM properties can be coupled in the governing equations conveniently. The finite element method not only has advantages of adjustable visualization and friendly user interface, but also predicts more precisely. The multi-physics software makes the thermal field and electrical field compatible, as well as other physics field. It makes it possible for researchers to learn other properties of the TEM, such as the mechanical properties, thermal, and electrical properties.

### SUMMARY OF THE INVENTION

The present invention relates to generating electricity from a heat utilizing thermoelectric modular generally located in a pavement. More specifically, a thermoelectric-based energy harvesting system, comprising: a thermoelectric module comprising an upper surface and a lower surface, said upper surface being separated from said bottom surface by a “n” type material, or a “p” type material, or both; said thermal electric module operatively adapted to be in contact with a heat source, a thermally conductive plate is located beneath said thermoelectric module, said plate being capable of transferring heat from said thermoelectric module lower surface to a heat sink via a thermally conductive leg that thermally engages said plate; and said system capable of generating electricity therefrom. The thermoelectric generator proposed is unique in that it is flexible and can be fabricated by printing, it, therefore, can accommodate deflection of road under traffic load (which will damage conventional thermoelectric generator unit) and will ensure the durability.

### BRIEF DESCRIPTION OF THE DRAWINGS

FIG. 1 shows a summary of the state-of-art TE materials, black bars represent p-type materials and gray bars represent n-type materials; by using parallel structure, we achieved much higher performance using regular materials compared with the expansive state of art materials;

FIG. 2 shows TEM with Π structure. Temperature gradient is in cross-plane direction. Substrates are rigid. (a) the whole TEM; (b) Unit TEM;

FIG. 3 shows a multi-layered stack structure, in-plane thermal flux, flexible substrate;

FIG. 4 shows a roll-up sheet structure, cross-plane thermal flux, flexible substrate;

FIG. 5(a) relates to a uni-leg structure, cross-plane thermal flux and rigid substrate with an overlayer having high thermal conductivity on the TEM, whereas FIG. 5(b) also relates to an overlayer.

FIG. 6 shows a traditional TEM is electrically in series of one p-leg and one n-leg, or two p-legs and two n-legs that is a voltage source;

FIG. 7 shows an electrically parallel TEM where TE legs are considered as current source. (a) p-type (b) n-type;

FIG. 8 shows an example of daily temperature variations across a pavement structure, indicating that the subgrade temperature maintains approximately at a constant temperature beyond a certain depth;

FIG. 9 shows a schematic of the TE energy harvesting system of the present invention;

FIG. 10 shows a TE module's output power vs thermal insulator length;

FIG. 11 shows a temperature field distribution across the pavement structure wherein the upper aluminum rod is lower than the surroundings, and that in the lower rod, the situation is reversed;

FIG. 12 shows an experiment set up in the lab, (a) an aluminum plate and rod that is covered by a thermal insulator placed through a hole in an asphalt-concrete base; (b) the upper surface of the aluminum plate covered with epoxy and then covered with a thermocouple, (c) a TEM placed on a top surface of the aluminum plate;

FIG. 13 shows a picture of the entire experiment setup wherein a TEM is placed upon an asphalt concrete pavement located on top of a sand base, right hand side of photo, and a table top having NI USB 6251 data acquisition board thereon, energy accumulation circuit, and Pico TC-08 data acquisition board;

FIG. 14 shows a diagram of the back-end energy management circuit;

FIG. 15 shows a monitored temperature process at different locations in the TE energy harvesting system;

FIG. 16 shows (a) voltage profiles at the TE element output electrode, capacitor and LED, (b) zoom in between 120 to 125 min;

FIG. 17 shows the installation process of the TE energy harvesting system outdoors;

FIG. 18 shows locations where temperatures were monitored;

FIG. 19 shows temperature data of two consecutive summer days;

FIG. 20 shows output voltage of the TEM with 10Ω load resistor. The corresponding temperature difference between two boundaries of the TEM is also plotted;

FIG. 21 shows the calculated output power data with time;

FIG. 22 shows the bottom heat treatment of the asphalt concrete samples with a silicone heat transfer compound that is then covered with aluminum foil;

FIG. 23 shows a heat sink as a heat exchanger used in control group wherein a heat sink was placed on the surface of the ground;

FIG. 24 shows temperature monitoring locations U of a TE energy harvesting system;

FIG. 25 shows temperature data for 20 consecutive summer days;

FIG. 26 shows temperature data zoomed in to the second and third day;

FIG. 27 shows output voltage comparison between two types of A1 heat exchangers;

FIG. 28 shows output power comparison between the two different types of heat exchangers;

FIG. 29 shows temperature sensor locations inside an asphalt concrete layer of the pavement structure;

FIG. 30 shows testing locations of the data involved in the calculations of this invention;

FIG. 31 shows the average temperature gradient across the pavement structure in a year. The unit of the numbers in the figure is K/m;

FIG. 32 shows the average temperature gradient across the pavement structure in January. The unit of the numbers in the figure is K/m;

FIG. 33 shows the average temperature gradient across the pavement structure in July. The unit of the numbers in the figure is K/m;

FIG. 34 shows a compilation of thermoelectric energy harvesting from pavement and infrastructure, wherein the upper-left photo is of a highway system wherein the TEMs of the present invention can be implanted, wherein the upper-right picture is a duplicate of FIG. 31 of the present invention, wherein lower-left figure is a duplicate of FIG. 11 of the present invention, wherein the lower-center picture is a duplicate of FIG. 9 of the present invention, and wherein the lower-right figure is a duplicate of FIG. 27 of the present invention.

### DETAILED DESCRIPTION OF THE INVENTION

TE Materials

TE materials that form TEMs have fundamental influence on the module behaviors. Researchers have been working on either finding or developing new TE materials that can lead to higher intrinsic efficiency and lower material cost. TE materials that have been investigated can be categorized into three groups: semiconductors, semiconducting oxide ceramics and polymers. Among them, semiconductor TE materials possess relatively higher intrinsic efficiency, but they are typically made from high atomic weight elements with small band-gaps and high-mobility carriers. The material resources on earth are rare and frequently environmentally unsafe, which consequently lead to high material cost. In contrast, metal oxide ceramics and polymers are significantly more abundant and cost-effective. But they have tremendously lower intrinsic efficiency and higher inner resistance.

In addition to selecting from the existing known materials, researchers are also dedicated to create new materials where the carrier (electron, hole, phonon, etc.) transport performances can be engineered to increase the intrinsic efficiency. There have been two primary approaches to achieve this goal: synthesizing new complex solid-state materials that have complex crystal structures, such as Skutterudite, Clathrate, Half-Heusler materials; as well as creating nanostructured materials, such as nanocomposites (3D), superlattices (2D), nanowires (1D), and quantum dots (0D).

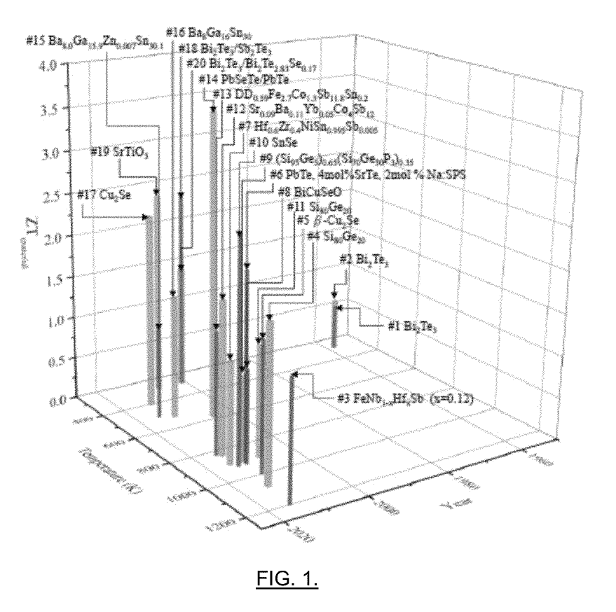

The state-of-the-art thermoelectric materials with the high figure-of-merit (ZT) value are summarized in FIG. 1 and Table. 1-1. The ZT value determines the overall TEM energy efficiency. The higher the ZT, the higher the energy efficiency. The ZT value of a certain TE material can be calculated based on the material's Seebeck coefficient α, electrical conductivity σ (or resistivity ρ), the thermal conductivity κ and the working temperature T, shown as equation (1.1).

$$ZT = \frac{{α}^{2} σ}{κ} T = \frac{{α}^{2}}{ρκ} T \qquad ( 1.1 )$$

Although high intrinsic material efficiency has been reported for many TE materials, it comes at the expense of fabrication cost. Researchers have struggled to balance between the efficiency and cost. A new solution to simultaneously improve the efficiency and decrease the cost of the TE technology is desperately needed.

TABLE 1-1

| | | | | α | ρ | κ | | | |
|---|---|---|---|---|---|---|---|---|---|
| # | TE materials | Comments | p/n | (μV/K) | (mΩ · cm) | W/(m − K) | T(K) | ZTₘₐₜₑᵣᵢₐₗ | Year |
| 1 | Bi₂Te₃ | Crystal, doped | p | 190.94 | 1 | 1.95 | 300 | 0.56 | 1958 |
| 2 | Bi₂Te₃ | Crystal, doped | n | −201.75 | 1 | 1.91 | 300 | 0.64 | 1958 |
| 3 | FeNb₁₋ₓHfₓSb (x = 0.12) | Half-Heusler, heavy-band | p | 2.46.41 | 1.23 | 4.15 | 1200 | 1.42 | 2015 |
| 4 | Si₈₀Ge₂₀ | Nanostructured, P doped | n | −284 | 5.01 | 0.93 | 1073 | 1.84 | 2014 |
| 5 | b-Cu₂Se | Phonon-liquid and electron crystal | p | 295.12 | 7.70 | 0.74 | 1000 | 1.53 | 2012 |
| | | (PLEC), phase change | | | | | | | |
| 6 | PbTe, 4 mol % SrTe, 2 mol % | High temperature, all scale | p | 283 | 3.45 | 0.95 | 915 | 2.2 | 2012 |
| | Na: SPS | hierarchical structure | | | | | | | |
| 7 | Hf_{0.6}Zr_{0.4}NiSn_{0.995}Sb_{0.005} | Half-Heusler without nanostructure, | n | −223.15 | 1.04 | 3.64 | 900 | 1.2 | 2015 |
| | | annealed at 1350° C. for 30 min. | | | | | | | |
| 8 | BiCuSeO | Ba heavily doped, carrier | p | 181.81 | 5.57 | 0.49 | 923 | 1.1 | 2012 |
| | | concentrations as | | | | | | | |
| | | high as 1.1 × 10²¹ cm⁻³ | | | | | | | |
| 9 | (Si₉₅Ge₅)_{0.65}(Si₇₀Ge₃₀P₃)_{0.35} | nanocomposites | n | −245.32 | 1.28 | 4.42 | 900 | 1.0 | 2012 |
| 10 | SnSe | crystal b axis, high temperature, | p | 342 | 11.93 | 0.35 | 923 | 2.6 | 2014 |
| | | layered and anisotopic crystal | | | | | | | |
| | | structure | | | | | | | |
| 11 | Si80Ge20 | Nanostructured, B doped | n | −250 | 1.78 | 2.50 | 900 | 1.3 | 2008 |
| 12 | Sr_{0.09}Ba_{0.11}Yb_{0.05}Co₄Sb₁₂ | Skutterudies, high temp, after severe | n | −203 | 0.92 | 2.04 | 835 | 1.8 | 2014 |
| | | plastic deformation (SPD) via high- | | | | | | | |
| | | pressure torsion (HPT), T up | | | | | | | |
| 13 | DD_{0.59}Fe_{2.7}Co_{1.3}Sb_{11.8}Sn_{0.2} | Skutterudites, high temp, after high- | p | 181 | 1.51 | 1.25 | 825 | 1.44 | 2015 |
| | | pressure torsion (HPT), T increase | | | | | | | |
| 14 | PbSeTe/PbTe | Quantum-dot superlattices (QDSL), | n | −401.31 | 5.31 | 0.49 | 580 | 3.6 | 2005 |
| | | Bi doped | | | | | | | |
| 15 | Ba_{8.0}Ga_{15.9}Zn_{0.007}Sn_{30.1} | Clathrate, single crystal | p | 398.89 | 8.20 | 0.91 | 500 | 1.07 | 2015 |
| 16 | Ba₈Ga₁₆Sn₃₀ | Clathrate, doped with Cu | n | −261.32 | 3.64 | 0.67 | 520 | 1.45 | 2012 |
| 17 | Cu₂Se | Phonon-liquid and elctron crystal | n | −166.5 | 2.4 | 0.2 | 400 | 2.3 | 2013 |
| | | (PLEC), phase change | | | | | | | |
| 18 | Bi₂Te₃/Sb₂Te₃ | Superlattice, 10 Å/50 Å, 2.67 μm | p | 142.33 | 0.53 | 0.49 | 300 | 2.34 | 2001 |
| | | thick, carrier concentration of | | | | | | | |
| | | 9 × 10¹⁸ cm⁻³ | | | | | | | |
| 19 | SrTiO₃ | Metal oxide, 2DEG supperlattice | n | −850 | 0.75 | 12 | 300 | 2.4 | 2007 |
| 20 | Bi₂Te₃/Bi₂Te_{2.83}Se_{0.17} | Superlattice, 10 Å/50 Å | n | −238 | 1.23 | 0.945 | 300 | 1.46 | 2001 |

### Current TEM Structures

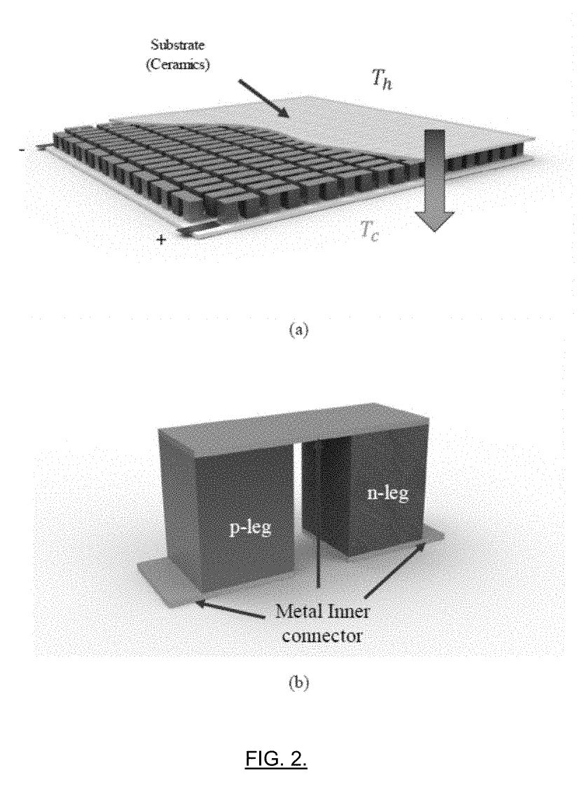

The most widely used TEM at present is composed of p-type and n-type materials that are connected thermally in parallel and electrically in series. For bulk TE materials, including nanocomposites fabricated using bulk process, the most popular device structure is the so-called Π structure, shown in FIG. 2, where the temperature gradient is along the cross-plane direction, which is suitable for most TEG applications. However, the spatial zigzag structure of p-legs and n-legs inevitably leaves spaces among TE legs (i.e. fill factor<1), which deteriorate the device's volume power density and mechanical durability. Meanwhile, the fabrication process of this zigzag structure is relatively complicated, resulting in a high fabrication cost. In addition, the module is usually supported using hard substrate materials, such as ceramics, in order to provide mechanical support and electrical insulation from the ambient environment. Consequently, TEM using Π structure is not flexible, which severely limits the application of TEM in areas of soft surface energy conversion, such as the human body skin-based energy generation to power consumer electronics.

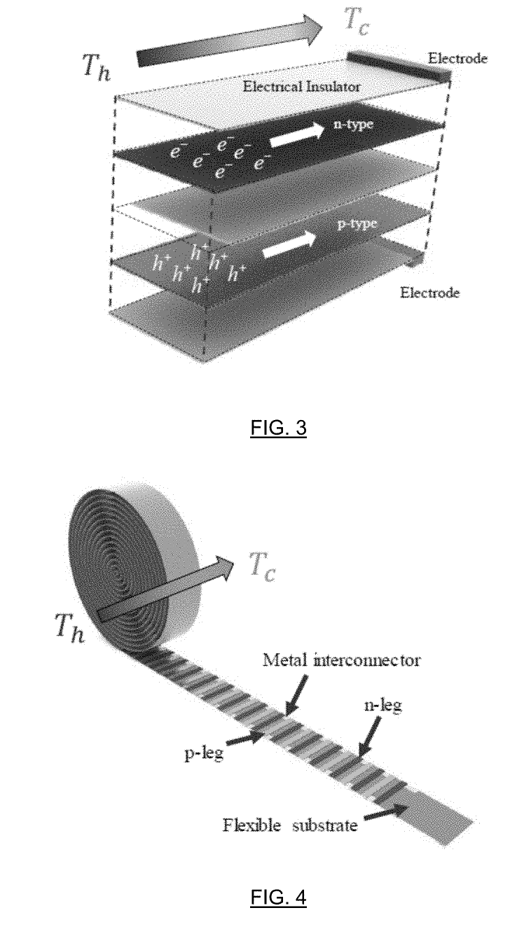

For film TE materials, such as superlattices, quantum dots, and TE inks, the TE device structure can be either the layered stack structure as in FIG. 3, or the roll-up sheet structure as in FIG. 4. The TEM using multilayered-stack structure can be flexible. However, the temperature gradient has to be applied along the in-plane direction, which still dramatically limits the application. It has to be pointed out that even though the substrate in the roll-up sheet structure can be flexible, the final device is usually rigid after rolled-up. The device area is usually limited by the length of the substrate. Temperature gradient is along the in-plane direction for the substrate, but not along the cross-plane direction for the roll-up module.

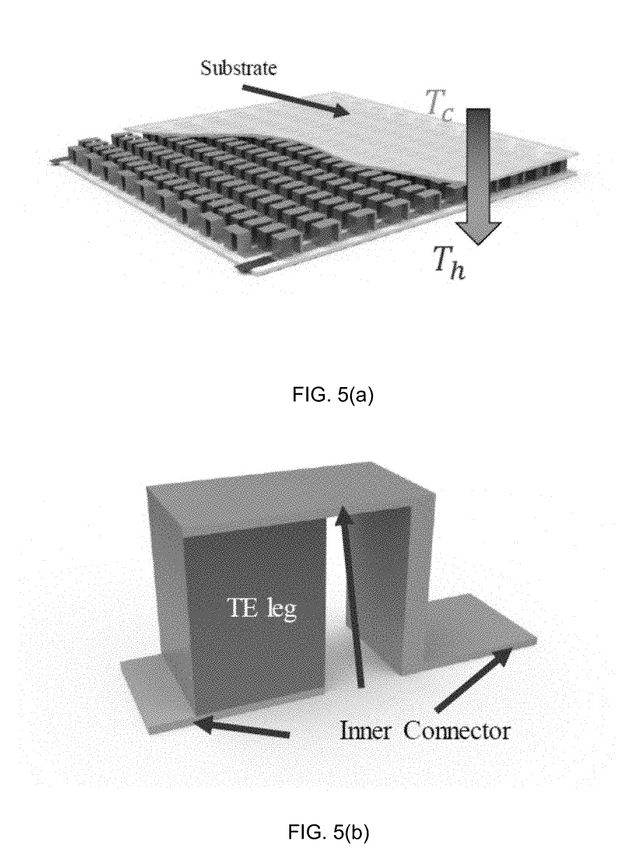

All the Π structure, multilayered stack structure and the roll-up sheet structure are made up by two different types of TE materials, resulting in a different thermal expansion rate. It severely impacts the lifetime of TEM, especially when working under high temperature region and periodical temperature boundary conditions. In order to increase the reliability, a uni-leg device structure is proposed, as shown in FIG. 5, where only one type of TE material (either n-type or p-type) makes up the TEM. However, the module's energy efficiency is dramatically decreased. It is equivalent to that one type of high efficiency TE material is replaced by metal, compared to other aforementioned structures.

All the four types of structure introduced above follow the principle where all TE legs are connected electrically in series, which makes the TEM vulnerable to environmental or artificial deterioration. Even a single break in any contact between the TE materials and the metal inner connectors can lead to the function failure of the TEM. This problem is even severe for the first three types of TEM structures, because of the potential mismatch of thermal expansion between n-type and p-type TE materials. Meanwhile, the device surface area is also limited because of the complicated device structure.

Hence, an innovative TE device structure that can overcome all the aforementioned contradictions will significantly benefit the applications of the TE technology. An ideal TEM should have cross-plane temperature gradient, possibility to be flexible, high energy efficiency, low fabrication cost, immunity to ambient damage and have a large surface area.

TEG can directly convert heat energy to electric energy. Once provided a temperature gradient across the device, TEG can produce power to its electric load. TEG has been widely used for decades. The power production ranges over 15 orders of output power magnitude from milli-microwatt all the way up to multi-hundred megawatt. TEG applications can be conveniently categorized by its source of heat: fossil fuel, nuclear decay, waste heat, solar thermal energy, etc.

The temperature gradient for the TEG can be directly generated by burning fossil fuel, under situations where either the fossil fuel in the specific application location is abundant and cost-effective or other types of energy resources are not accessible. For example, fossil-fueled TEGs are utilized to provide cathodic protection for pipelines that deliver natural gas in remote areas. However, this type of application is limited because of the possibility of environment pollution and the constraints of fossil fuel sources.

The TEG powered by nuclear decay is an ideal option for applications in remote, inaccessible and hostile environments, such as in outer space and undersea. The heat source from nuclear materials has a long lifetime and high energy density. However, this type of applications is limited due to the high cost and radiation of the nuclear reactor.

TEG for civil uses are typically driven by waste heat from plants, vehicles, heat pipes, microprocessors, human bodies, etc. These types of applications are significant because vast quantities of produced energy are discarded into the earth's environment as waste heat that are too low grade to be recovered using other conventional electrical power generators. Thermoelectric power generators can also be driven by solar thermal energy, which is a green energy source that helps to reduce the fossil fuel uses. The solar thermal energy has low energy density resulting in low temperature gradient. Methods such as the use of lenses or locating the TEGs in greenhouses have been studied to concentrate the solar heat.

The applications of TEG are still limited mostly by the low-energy efficiency and high cost. However, there are various types of naturally existing temperature gradient that have not been taken advantage of. For example, the temperature gradient across the pavement structure, the windows of buildings or automobiles, human body skins, etc. Harvesting energy from those free-of-cost energy resources using TE technology can still be economical.

The applications of TEG are also limited partially by the complexity of heat exchanger design at the TEM cold side, which also plays a significant role in improving the energy TE harvesting system's efficiency. The cooling agent of the heat exchanger that takes away the discarded heat from the cold side of the TEM is usually air, water, liquid nitrogen, etc. Heat exchanging efficiency can be optimized through adjusting the contact area between the cold side of the TEM and the cooling agent (such as by using metal fin structure) or adjusting the cooling agent's speed or volume when flowing by (such as utilizing fans, valves, etc.). All these heat exchanger designs complicate the system at the cold side of the TEG, which further limits its application.

In order to make use of the naturally existing temperature gradient based on TE technology, innovative energy harvesting system needs to be designed. Firstly, high intrinsic energy efficiency, low cost and large surface area TEM should be developed while keeping the temperature gradient in the cross-plane direction. Secondly, a heat exchanger at the cold side of the TEM that has low complexity and high feasibility when applied to large area energy harvesting scenarios needs to be realized.

### Overview of Invention

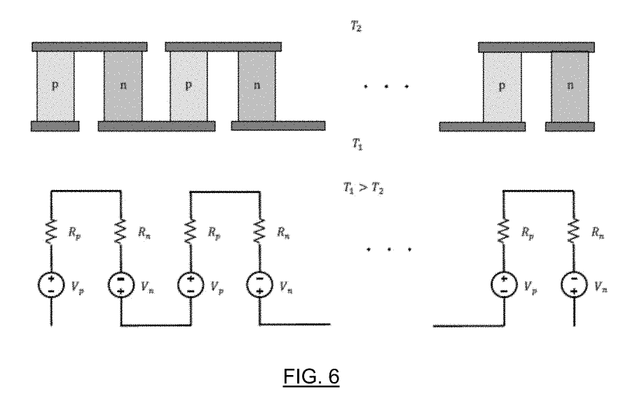

The traditional TEM structures are all electrically in series. Each TE leg has been considered as a voltage source with a finite inner resistance, as shown in FIG. 6. The TEM's overall open-circuit output voltage is a superposition of each TE leg's open-circuit output voltage. However, the short-circuit current still remains small.

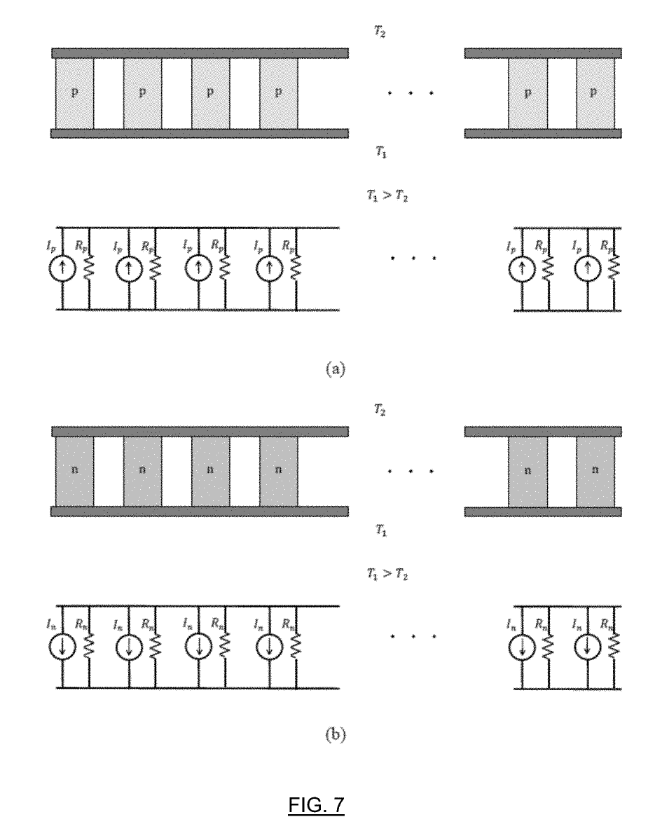

The ultimate goal of TE research is to increase the output power of TEG, which equals the product of output voltage and output current corresponding to a certain load resistance. Traditional TEMs using electrically serial structure enhance the output power through increasing the output voltage. However, there should be another path to increase the output current by connecting the TE legs electrically in parallel, where only one type of TE material (either n-type or p-type) is used, shown in FIG. 7. Each TE leg is treated as a current power source. The current source is still equivalent to the voltage source based on Thévenin's theorem with respect to the output characteristics.

Aging infrastructures require a proactive strategy to ensure their functionality and performance. Innovative sensors are needed to develop intelligent and durable infrastructures. A power supply strategy is among the crucial components to reduce cost and to ensure the long-term function of these embedded sensors. Fortunately, a TEM-based energy harvesting system can meet these requirements and directly collect energy from the temperature gradient across the pavement structures in situ to power those types of sensors.

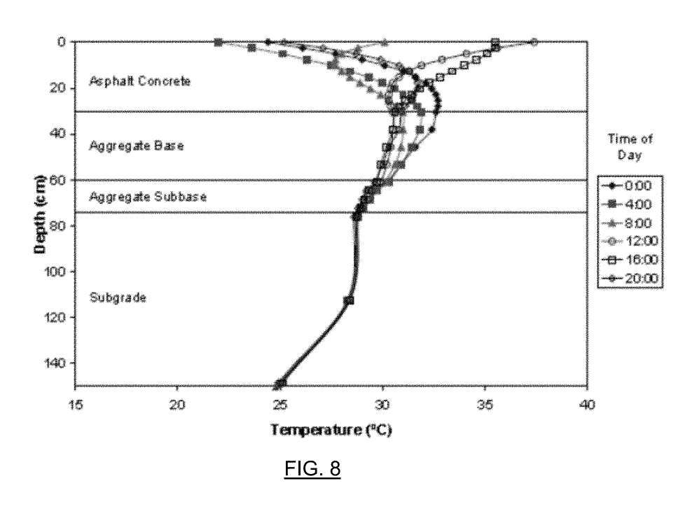

FIG. 8 shows an example of daily temperature variations across pavement structures, indicating that the subgrade temperature maintains approximately at a constant temperature beyond a certain depth (around 80 cm in this example). This constant temperature implies that the subgrade of the pavement structure can serve as a heat sink to dissipate the heat absorbed from the top side of the TEM. A thermal gradient of variable magnitude exists between asphalt concrete layer of the pavement and its subgrade throughout a day, serving as a potential energy source for electricity generation using TE devices. Even though there are occasions in which the temperature gradient may be small or nonexistent, these occasions are a relatively short period of time that do not dramatically impact the performance of the energy harvester.

The explorations for this study are introduced as follows. The heat exchanger at the cold side of the TEM is first optimized, using computer-aided finite element simulation, as introduced in Section 2. In-lab and outdoor experiments are then introduced in Section 3 and Section 4, respectively. In Section 5, the amount of energy harvested from pavement structures using the TE technology is compared among many states in the U.S. by comparing the average absolute-value temperature gradient across the asphalt concrete layer. The output density of the TEM is estimated as well.

Computer-Aided Optimization of Aluminum Heat Changer

The heat exchanger design at the cold side of the TEM is crucial for the performance of the TE energy harvesting system. In order to generate a large enough output power from the TEM, enough temperature difference between the upper and lower surface of the module needs to be maintained. The idea is to thermally connect a thermal conductive plate, in contact with or connected to the lower surface, to a heat sink such as subgrade soil as by a thermally convective leg (for example, an aluminum rod). To improve heat conduction, the thermal conductive leg material should be separated by thermal insulating material (such as foam) from its surrounding pavement environment.

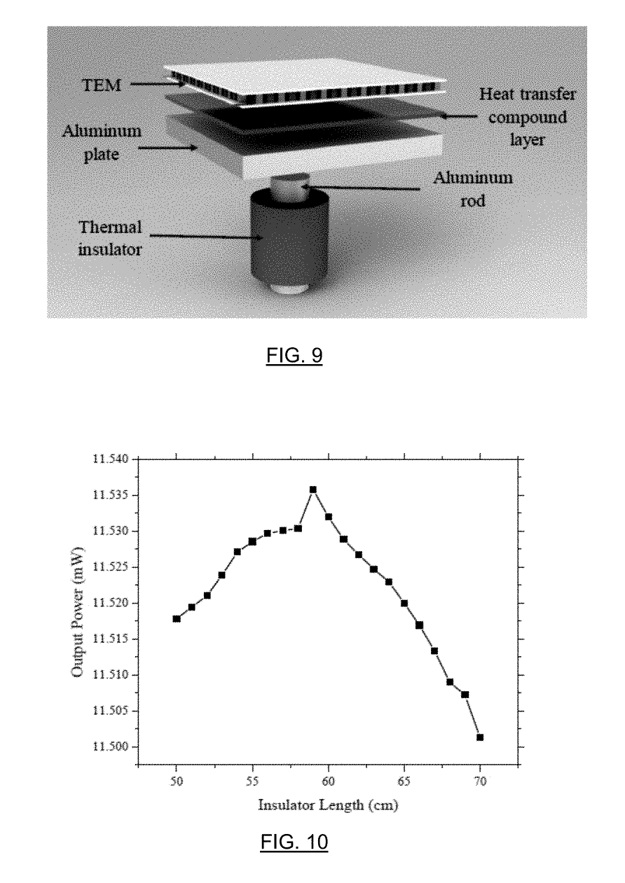

The schematic of the TE harvesting system design is demonstrated in FIG. 9. The system is comprised of TEM, an optional heat transfer compound layer, an aluminum plate, an aluminum leg that can be a rod, and a thermal insulator.

Although the newly-proposed electrically parallel TEM accommodates the energy-harvesting from pavements application better than the traditional electrically serial TEM, no mature electrically parallel TEM device was fabricated to handle the large mechanical loads required for that application. Therefore, in order to prove the concept of the energy harvesting system, commercial electrically serial TEMs were used instead for this study.

Considering typical pavement structures, the thermal conductive leg, e.g. an aluminum rod, was designed to be as long as 1 m, in order to make connections to the pavement subgrade. As a result, the only remaining significant parameter that needs to be optimized in the energy harvesting system is the length of the thermal insulator. If the insulator length is too long, the aluminum rod and the pavement subgrade soil will not be contacted sufficiently, weakening the heat exchange at the rod bottom and, consequently, decreasing the temperature difference between the upper and lower TE module surfaces. However, if the insulator length is too short, heat flux from the upper pavement soil surroundings will interfere with the heat flux within the aluminum rod, which does not benefit the energy harvesting system, either.

Computer model analyses can be utilized to improve the efficiency of the TEM of the present invention. For example, it has been found that a minimum TEM temperature gradient is at least 8° C., desirably at least 15° C., and preferably at least 22° C. or at least 27° C. Computer-aided finite element simulation helps to optimize the insulator length. Material properties and geometry parameters used in the simulation are listed in Table 1. Based on the data in Table 1, the insulator length is swept from 5 cm to 95 cm. The temperature difference between the upper and bottom side of the TEM can then be calculated. Based on the TEM's output characteristics provided by the manufacturer, the TE module's output power can then be calculated with respect to the thermal insulator length, shown as FIG. 10, zoomed in between 50 cm and 70 cm. According to the Figure, the optimum insulator length is 59 cm, which could produce power of 11.5 mW.

TABLE 1
Parameters and size definition of materials used in FEM simulations.

| | Heat | Thermal | | Width | Length | Depth |
|---|---|---|---|---|---|---|
| | Capacity | Conductivity | Density | (x axis) | (y axis) | (z axis) |
| Material | J/(kg*K) | W/(m*K) | kg/m³ | cm | cm | cm |
| Aluminum Plate | 900 | 160 | 2700 | 4 | 4 | 0.5 |
| Aluminum Rod | 900 | 160 | 2700 | Radius: 0.5 | | 100 |
| TE module | 2000 | 0.4 | 3125 | 4 | 4 | 0.48 |
| Thermal Insulator | 3000 | 0.04 | 1000 | Thickness: 1 | | 59 |
| Glue | 2000 | 60 | 1500 | 4 | 4 | 0.1 |
| Asphalt Concrete | 1200 | 1.6 | 2400 | 104 | 104 | 17.78 |
| Granular Base | 1400 | 1 | 2080 | 104 | 104 | 30.48 |
| Sub Base | 1600 | 0.8 | 1850 | 104 | 104 | 30 |
| Sub Grade | 1800 | 0.6 | 1800 | 104 | 104 | 71.74 |

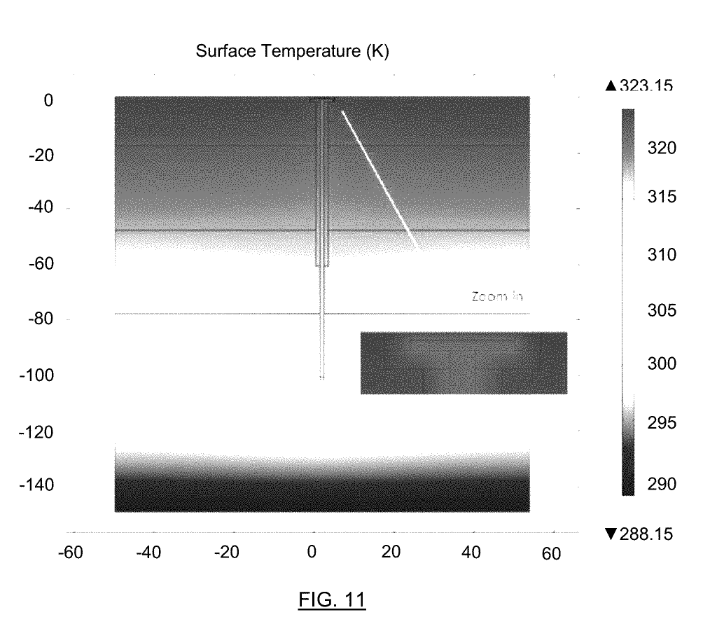

An example of thermal field distribution is shown in FIG. 11. In this simulation, the ground temperature was assumed to be 323.15 K. The temperature at the deep ground was assumed to be 288.15 K. FIG. 11 indicates that temperature in the upper aluminum rod is lower than the surroundings, whereas in the lower rod, the situation is reversed. This implies that heat flux gathers together from the surroundings of the aluminum plate, and then goes downwards via the high conductivity rod, and eventually dissipates into surroundings of the bottom aluminum rod.

In-Lab Experiment

The TE energy harvesting system was first tested in the lab, in order to have a stable environment control. The TEM was designed to sit on top of an asphalt concrete sample and to collect heat energy from the sample's top boundary, covered by a piece of black tape.

Experiment Setup

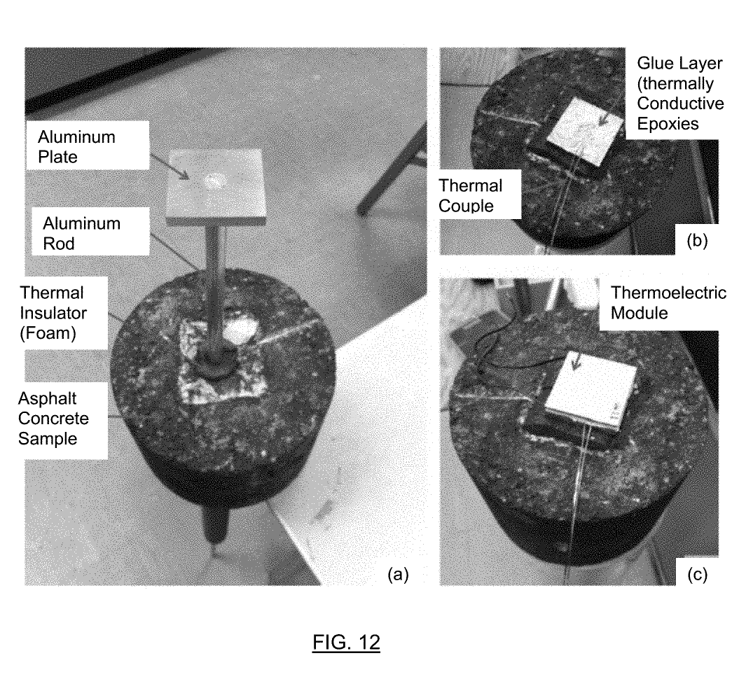

The experiment setup was as follows. First, a hole was drilled in the middle of a heat source such as an asphalt concrete sample, with a diameter of 15 cm and thickness of 10 cm. An aluminum plate and rod, which was covered by a thermal insulator, was placed through the hole (FIG. 12(a)). Sequentially, thermally conductive epoxies were spread over the upper surface of aluminum plate. Meanwhile, a thin thermocouple was also placed on top of the surface (FIG. 12(b)). Then, a TEM was installed on the surface of aluminum plate, with the thermally conductive epoxies as the interface (FIG. 12(c)). The whole set of equipment was surrounded by a heat sink such as sand, imitating the pavement subground environment. All equipment utilized in this setup was of the same size as the previous optimization simulation.

In order to systematically analyze the performance of the system, a comparatively stable heat source is preferred. Therefore, a filament lamp was utilized to heat the upper surface of the TE module, whose output voltage powers an energy management circuit, as discussed in Section 6.3.2.

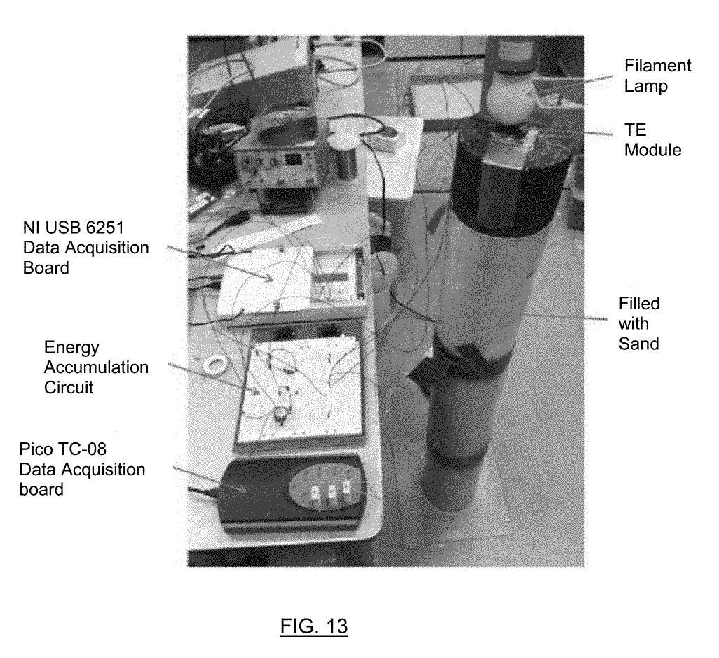

The picture of the entire experiment setup is shown in FIG. 13. Three temperature signals (temperatures at TEM upper surface, interface between TEM and aluminum plate, and aluminum rod bottom) were monitored using software.

Picolog Recorder and data acquisition device (DAQ) Pico TC-08. LabVIEW software and data acquisition board NI USB 6251 were also involved in this system to collect voltage data at the TE module output electrode, capacitor, and light-emitting diode (LED). The experiment duration was about 150 minutes.

Power Management Circuit

The aim of a power management circuit is to accumulate the converted energy into energy storage components, such as super capacitors, which have extremely long lifespans and can be charged and discharged thousands of times. It has been reported that a 10 F super capacitor stores enough energy to support mW consumption applications.

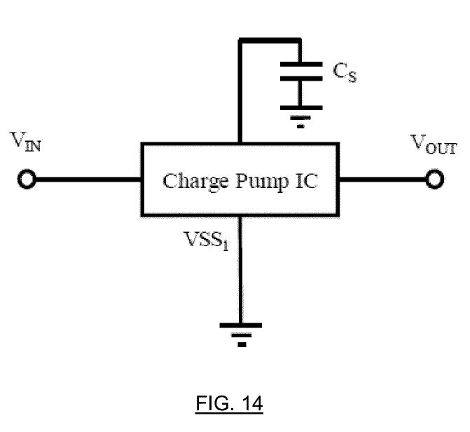

The output voltage generated by the TE is too low to directly power any electrical component, which usually requires a 0.7 V start-up voltage to work. Consequently, an ultra-low start-up voltage charge pump IC (S-882Z Series, Seiko) was used to amplify the output voltage, from 300 mV to a voltage higher than the start-up threshold. The pins of chips are connected as shown in FIG. 14.

During the charging cycle, the voltage of the super capacitor keeps increasing until it reaches the threshold of discharge voltage, from which the discharge cycle begins. Charges flow from the charged super capacitor to power the load. The capacitor in this study is 2200 μF. A light-emitting diode (LED) was used as a load.

Temperature Distribution

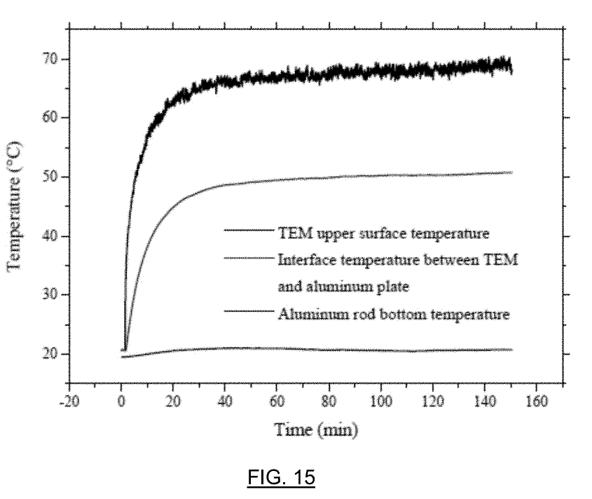

As shown in FIG. 15, the temperature of the TE module upper surface (top line in the Figure quickly increased as soon as the heat source (lamp) was turned on, approaching 70° C. from room temperature. The interface temperature between the TE module and the aluminum heat collection plate (middle line in the Figure also increased and became stable at 50° C. A 20° C. temperature difference was maintained between both sides of the TE module. The temperature at the bottom of the aluminum heat collection rod did not change significantly, indicating that heat flux coming from the aluminum plate mostly dissipated into sand surroundings before it arrived at the bottom of the heat collection aluminum rod.

The temperature difference between the TEM top surface and the TEM bottom surface (20° C.) only occupies 40% of the temperature difference between the TEM top surface and the aluminum rod bottom (50° C.). This implies that there is still much room to improve the heat exchanger design to further cool down the temperature at the TEM bottom surface.

Electric output of the TE energy harvesting system

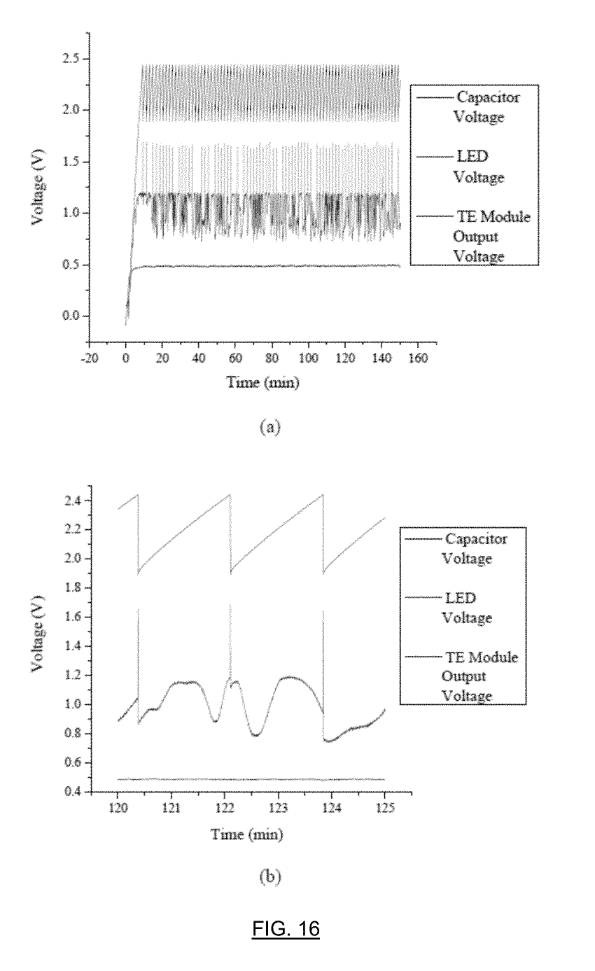

FIG. 16(a) shows the voltage profiles at the output electrode of the TEM electrodes, the super capacitor, and the LED. FIG. 16(b) zooms in between 120 min to 125 min to show more details of the process. The following work sequence can be identified from the figures: When the temperature gradient was high enough for the TE module to generate 300 mV output voltage (the start-up voltage for the charge pump), the charge pump IC (Seiko, S-882Z) woke up and produced sufficient voltage to charge the capacitor. This caused the voltage at the capacitor to increase. Once the voltage in the capacitor reached 2.45 V, the charge pump IC automatically connected to the output and discharged the capacitor. Electrical energy stored in the capacitor flew into output pin. A 1.7 V DC voltage was generated to light up the LED. When the voltage in the capacitor dropped down to 1.9 V, the charge pump IC disconnected from the output pin.

The charge pump IC then turned into an ultra-low power sleeping mode. Meanwhile, the capacitor was charged again until the next working cycle started.

Energy contained in the capacitor is calculated through the following equation:

E_{cap}=½·C·B² (6.1)

Where C is ______ and V is voltage.

Each time when the capacitor discharged, its voltage dropped from 2.45 V to 1.9 V. Considering the capacitor's capacitance used in this circuit is 2200 μF, energy dissipated from the capacitor is 3.73 mJ per cycle. Assuming the energy discharging efficiency is η₂=50%, which means 50% of energy stored by capacitor could be transmitted to light the LED, the energy that is used to power the load is 1.86 mJ in each cycle.

According to the manual of the commercial TEM used in this study, the output power under 20° C. temperature gradient is about 50 μW. Considering that it takes 1.5 min (i.e. 90 sec) to charge the capacitor, the output energy of TEM per cycle is 4.5 mJ, resulting in a charging efficiency η₂=3.73/4.5=82.9%). Multiplying the charging efficiency with the discharging efficiency, the TEG energy harvesting system introduced in this section has the energy efficiency of about 41.5%.

As the capacitor involved here is only 2200 μF, energy stored in the capacitor can only power the LED for less than 1 s. A 0.47 F super capacitor was also tested, where the charge period was up to several hours and the LED could keep shining for several seconds. Therefore, there exists a tradeoff when choosing the proper capacitor. If the capacitor has a larger capacitance, the system could be applied to power load that works less frequently but longer. If the capacitance is smaller, the capacitor charges faster, but with less energy.

Outdoor Experiment.

The TE energy harvesting system was also tested outdoors to evaluate the energy harvested in the field. The back-end energy management circuit is not involved in this case, in order to reduce the data acquisition failure risk resulting from the versatile outdoor environments.

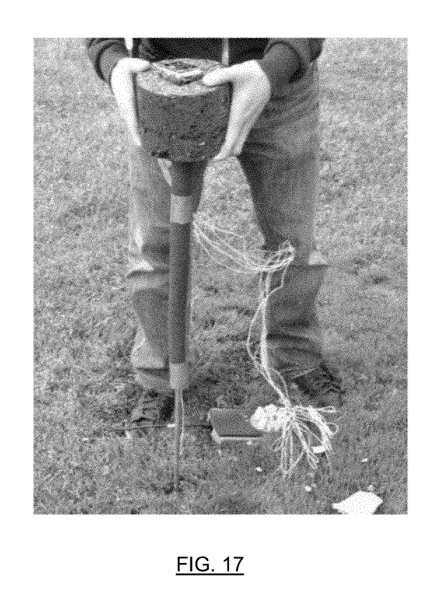

In this study, a 1 m-deep hole was drilled into the ground. Then, the whole TE energy harvesting system was inserted into the hole, as shown in FIG. 17. The hole was then refilled with dry sand to ensure thermal contact between the bottom part of the aluminum rod and the surrounding soil environment. Moderate water was introduced into the hole to guarantee high-enough thermal conductivity of the sand at the bottom of the aluminum rod.

TEM is placed on top of a heat source such as an asphalt concrete sample.

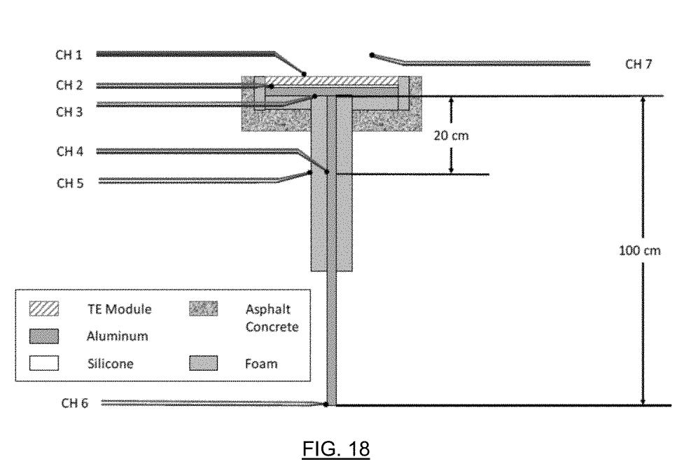

First, the TE energy harvesting system setup was designed identically to the case in the lab, where the TEM was placed on top of the same asphalt concrete heat source and collected heat energy from the sample's upper boundary. The TEM can be connected to a heat source that is adjacent to, within, or in, or otherwise operatively in contact with the heat source. Temperatures of more locations were collected, as shown in FIG. 18.

Initially, closed-circuit condition was attempted, where the TEM powered a 10Ω load resistor. However, the dew in the outdoor environment impacted the circuit and data collection. Therefore, open-circuit output voltage of the TEM was collected instead. All the temperature data and voltage data were collected using a data acquisition device (DAQ) CR1000 (CAMPBELL Scientific Inc.), which was powered by a 12 V, 5 Ah lead-acid battery (UB1250). All of the equipment was covered in a large-enough plastic box, leaving a hole to connect all the sensor wires through.

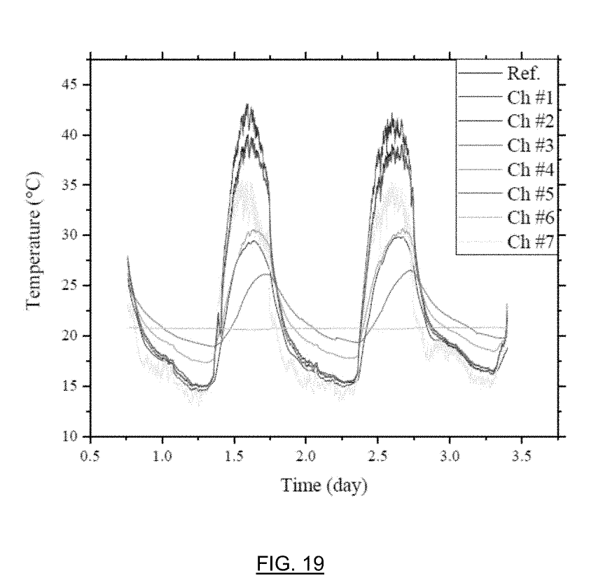

The data throughout two consecutive sunny summer days (September 16-17) was recorded. The temperature data is shown in FIG. 19. The black curve is the reference temperature on the DAQ board. During the daytime, the maximum temperature difference between top (Ch #1) and bottom surfaces (Ch #2) of the TEM was about 3° C. The temperatures at the top (Ch #2) and bottom surfaces (Ch #3) of the aluminum plate were approximately the same, indicating a good thermal conductivity of the aluminum plate. The inside (Ch #4) of the thermal insulator had a significantly higher temperature than the outside (Ch #5). This means that the aluminum rod conducts extensive heat energy downwards to the bottom of the system. The bottom temperature of the aluminum rod (Ch #6) remained stable throughout the whole testing period, implying that the aluminum rod's length was moderate and that the subgrade of the soil environment served as a good heat sink. During the nighttime, the temperature difference across the TEM was nearly zero, leading to a negligible output power.

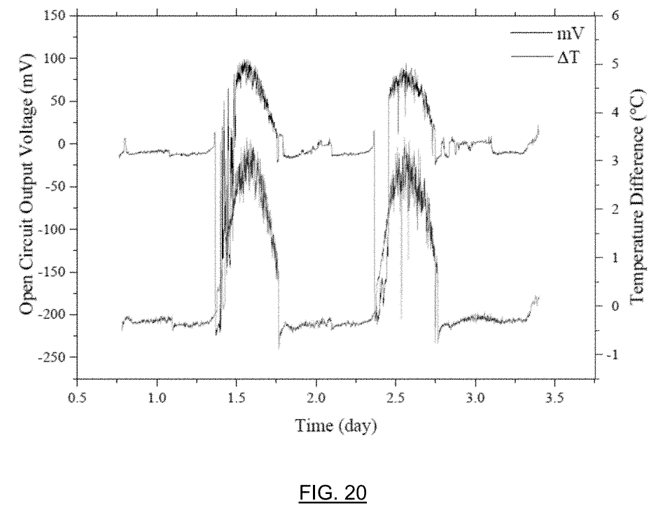

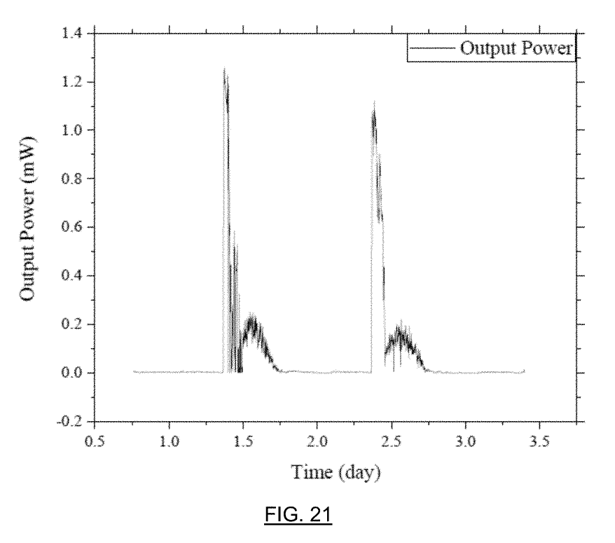

The open-circuit output voltage with respect to the corresponding temperature difference between two ends of the TEM is plotted in FIG. 20. Output power is plotted in FIG. 21, given the inner resistance of the TEM is about 10Ω and assuming the system was working under the maximum power delivering point where the load resistance matches with the inner resistance of the TEM. The total output energy during the first day was then calculated as about 8 J through the integration of FIG. 21. This indicates that the average maximum output power of the system is 92.6 μW. The peak output power is on the order of mW, shown in FIG. 21.

TEM is placed within (beneath) the asphalt concrete sample.

The asphalt concrete layer of the pavement structure is actually a promising heat collector, i.e. heat source, because of its dark color and decent thermal conductivity (on the order of 1 W/K/m). The implementation of TEM beneath the asphalt concrete layer can utilize this natural heat collector, which might improve the output power of the TE energy harvesting system. In addition, placing the TEM beneath the asphalt concrete layer hides the TEM, resulting in a more aesthetically appealing appearance, and a longer service life without deterioration from the ambient environment. This setup also helps in specific areas where the powering system needs to be confidential.

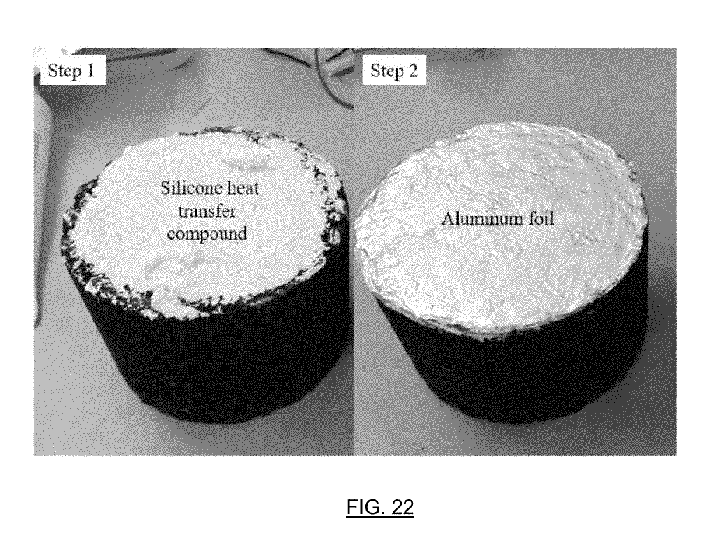

In order to take advantage of the heat collected by the asphalt concrete heat source to the largest extent, the bottom surfaces of the asphalt concrete samples (diameter of 10 cm, thickness of 6.5 cm) were first painted with silicone heat transfer compound (MG Chemicals, 860-150G) and then covered by aluminum foil, as shown in FIG. 22.

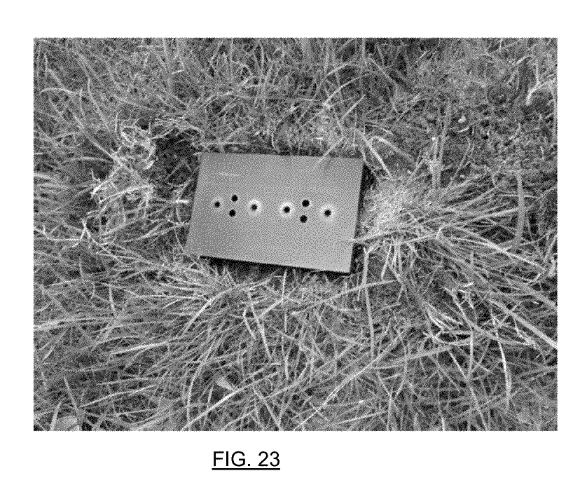

Then, the TEMs were placed beneath the asphalt concrete samples and on top of heat exchangers with silicone heat transfer compound as interface layer to enhance the heat conduction. As implied by the in-lab and outdoor experimental observations in Section 3.3 and 4.1, the heat exchanger design of using aluminum rods does not seem as efficient as expected. Therefore, in this section, another type of heat exchanger was explored: a heat sink shown in FIG. 23, buried into the shallow surface of the ground.

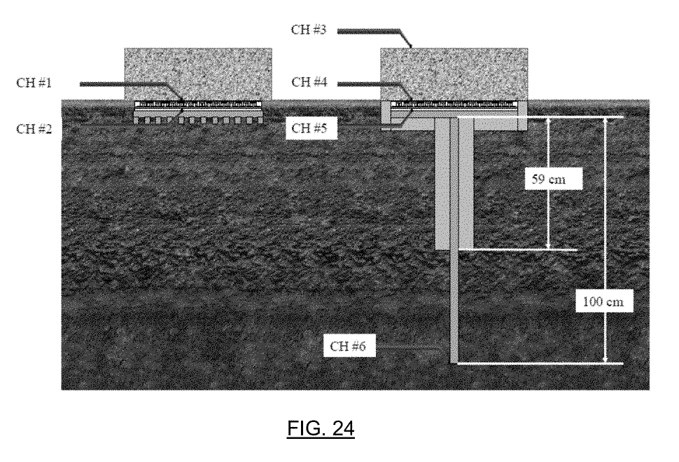

The temperature sensor locations are shown in FIG. 24 for both TE energy harvesting systems, based on two types of heat exchangers at the cold side of the TEMs. Open circuit voltages of the two systems were also collected. All data was recorded using the same DAQ setup as introduced in Section 4.1.

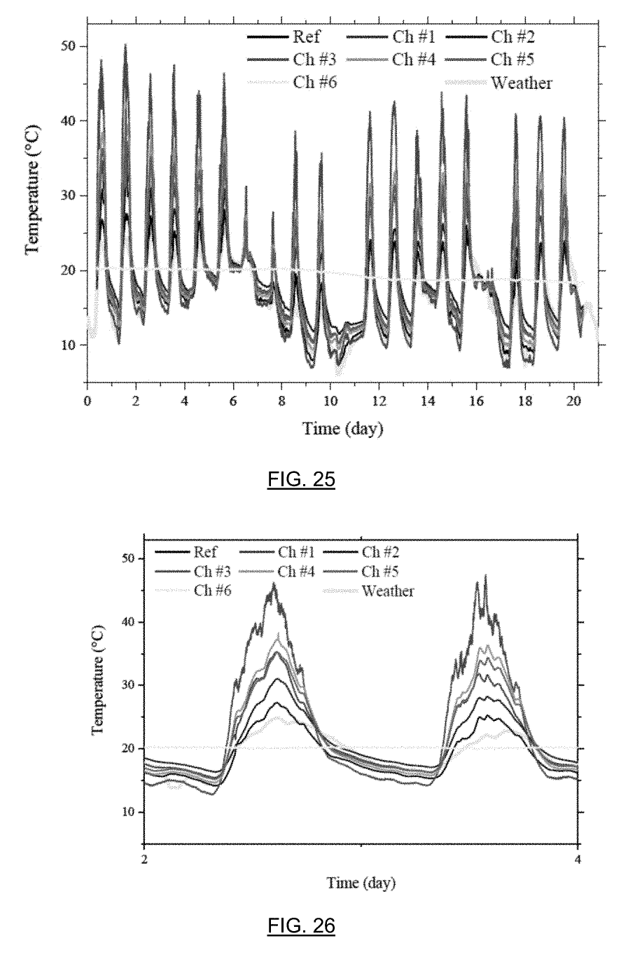

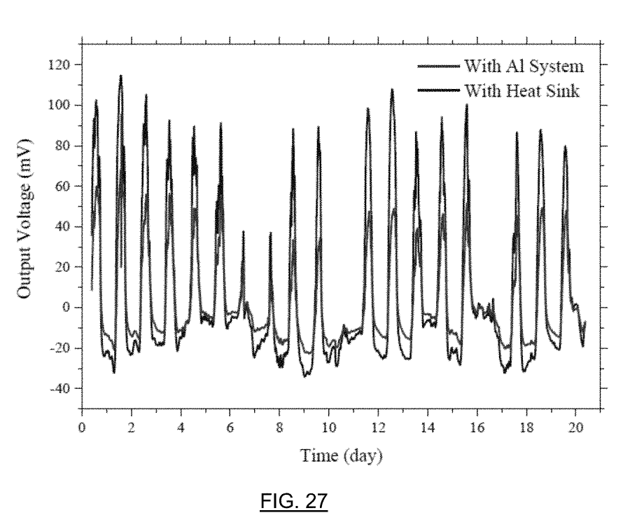

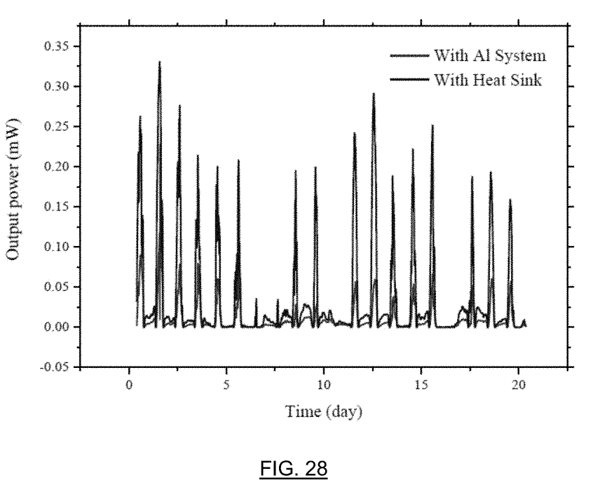

Temperature data of all channels and open-circuit output voltage data were recorded for about 20 consecutive summer days (from September 23 to October 13). The temperature data throughout the full time span is plotted in FIG. 25. FIG. 26 zooms in to show the temperature data for the second and third day. In addition to the collected temperature data, corresponding weather temperature data in the same period of time in Cleveland, Ohio is also plotted in the two figures as a reference (downloaded from www.wunderground.com). The open-circuit output voltage data with respect to the two types of heat exchangers is plotted in FIG. 27. Under the assumption that the TEM was working under the maximum power delivering point where the load resistance and the inner resistance of the TEM were both equal to 10Ω, the output power was calculated and plotted in FIG. 28.

FIGS. 25 and 26 match well with the trend of weather temperature data, which implies the collected experiment data is valid. The two Figures indicate that the temperature difference (Ch #4 and CH #5) across the TEM with aluminum heat exchanger is smaller than the temperature difference across the TEM with the heat sink as heat exchanger (Ch #1 and #2), resulting in a smaller output voltage and power, as shown in FIGS. 27 and 28. It seems that the aluminum heat exchanging system is not as efficient as the simple heat sink buried into the shallow surface of the ground.

However, this might not be the case when the two systems are implemented in real pavement structures. The experiment site in this study was on grass ground, where the surface temperature of the ground was relatively lower than the temperature in the field. Heat absorbed from the top boundary of the TEM could then easily dissipate into the surface layer of the grass ground. However, for the real pavement structure, the surface layer might have a high temperature during the summer daytime, where the aluminum heat exchanger system might still be more efficient.

For the TE energy harvesting system using the aluminum heat exchanger, the average output energy in a day is 0.86 J, with respect to testing time span of about 20 days. The average output power is about 10 μW. Peak output power is less than 1 mW. If the second day is taken as a sole example, when the weather is sunny and similar to the weather in Section 4.1, the total output energy on that day is 2.4 J. Average output power is 27 μW. Peak output power is about 0.2 mW. Compared to the data in Section 4.1, where the TEMs were placed on top of the asphalt concrete sample, the output power when the TEMs were placed beneath the asphalt concrete sample was relatively smaller. This does not necessarily mean that the asphalt concrete layer of the pavement structure is not a good heat collector (source). The asphalt concrete samples used in the experiment in this study have small diameters, resulting in limited heat energy collected from them. This might be the reason why the advantages of the placing the TEM beneath the asphalt concrete samples did not show up in the results. More experiments are still needed to be carried out in the field, to test the effectiveness of various heat exchangers.

Nationwide evaluation of TEM output energy harvested from pavements.

The experiments introduced in previous sections were all carried out on campus of Case Western Reserve University in Cleveland, Ohio. This section introduces the comparison of average thermal energy across pavement structures available for TE energy harvesting among different states in the U.S. The strategy is to first find the temperature gradient across the asphalt concrete layer of the pavement structures in each state. Then, the power density generated by TE energy harvesting system can be evaluated, given the efficiency of the TEMs.

Temperature gradient across asphalt concrete heat source layer of pavements.

In order to calculate temperature gradient across the asphalt concrete heat source layer of pavement structures in each state, temperature data at several given depths inside the asphalt concrete layer is required. This study utilizes the comprehensive database collected by the Long Term Pavement Performance (LTPP) program, composed of long-term historical data in most states, including data on pavement structures, climate, traffic, and pavement performance.

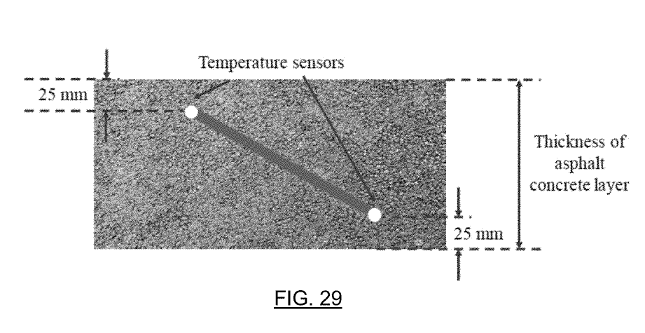

The temperature data within the asphalt concrete layer of pavements was extracted from table SMP_MRCTEMP_AUTO_HOUR collected by the Seasonal Monitoring Program (SMP) of the LTPP. It includes hourly temperature data collected at two individual depths, as shown in FIG. 29. The top sensor was located 25 mm beneath the top surface of the asphalt concrete layer, while the bottom sensor was placed 25 mm over the bottom boundary of the asphalt concrete layer.

First, the thickness of the asphalt concrete layer was extracted from table TST_AC01_LAYER from the General Information online database, where core samples of the pavement structures were measured. When many samples close to each other were measured corresponding to the same testing site, the thickness data was averaged.

Secondly, the hourly temperature gradient inside the asphalt concrete layer with respect to each testing site was calculated by dividing the temperature difference between the upper and lower temperatures, with the thickness of the asphalt concrete layer subtracted by 50 mm. The temperature gradient value is positive when the upper temperature is higher than the lower temperature. When the temperature conditions are reversed, the temperature gradient is negative. Therefore, the absolute values of the hourly temperature gradient with respect to a testing location were averaged within a pre-defined evaluation period (a year, or a month). When there were many testing sites in one state, the calculation results corresponding to each testing locations were also averaged to represent the state. When there were many years of data falling in the pre-defined evaluation period, the calculation results were also averaged. This is the final data used to be compared among different states. All the calculations introduced above were realized using MATLAB.

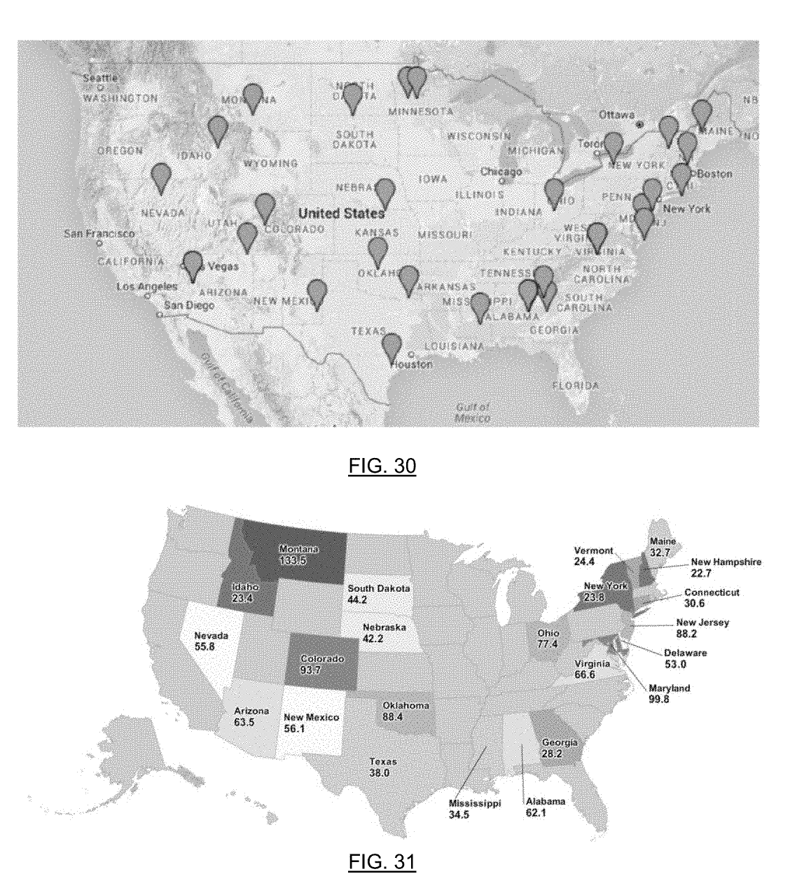

There are a total of 32 testing locations, but the raw data was taken from just 26 states, since certain states had multiple testing locations. The testing locations are highlighted in FIG. 30. Some location markers close to each other are overlapped, such as those in Alabama.

The raw data from the online database recorded the thickness changes resulting from construction projects, such as those deploying new overlay asphalt concrete layers on top of old layers. In the online database, whenever there was construction, the thicknesses of new samples were updated, while the temperature sensors were adjusted to maintain the setup as shown in FIG. 29.

The adjustment of the temperature sensor locations inevitably interrupts the temperature data collection, leading to data discontinuity. A parameter (Data Completeness) is defined as the ratio between the accumulated time length when there is effective data, and the total time length of a certain evaluation period. If the data completeness is less than 80%, the calculation is considered not convincing enough.

The calculation results of averaged absolute values of temperature gradients corresponding to each state within one year are shown in FIG. 31, which roughly indicates that the Southern part and Northeast coast of the U.S. have relatively small average temperature gradients. For the Southern states, such as Texas, the ambient temperature is continuously high, leading to little temperature change at the surface of the pavement. For the Northeast coast states, the temperature changes mildly, because of their oceanic climate, leading to small temperature gradients in those areas.

FIG. 31 also indicates that the average temperature gradient across the pavement structure throughout a year is higher in the Western mountain areas, such as Montana and Colorado, where the air temperature changes violently as sunshine changes, due to high altitudes. The TE energy harvesting technology fits best in those high altitude areas.

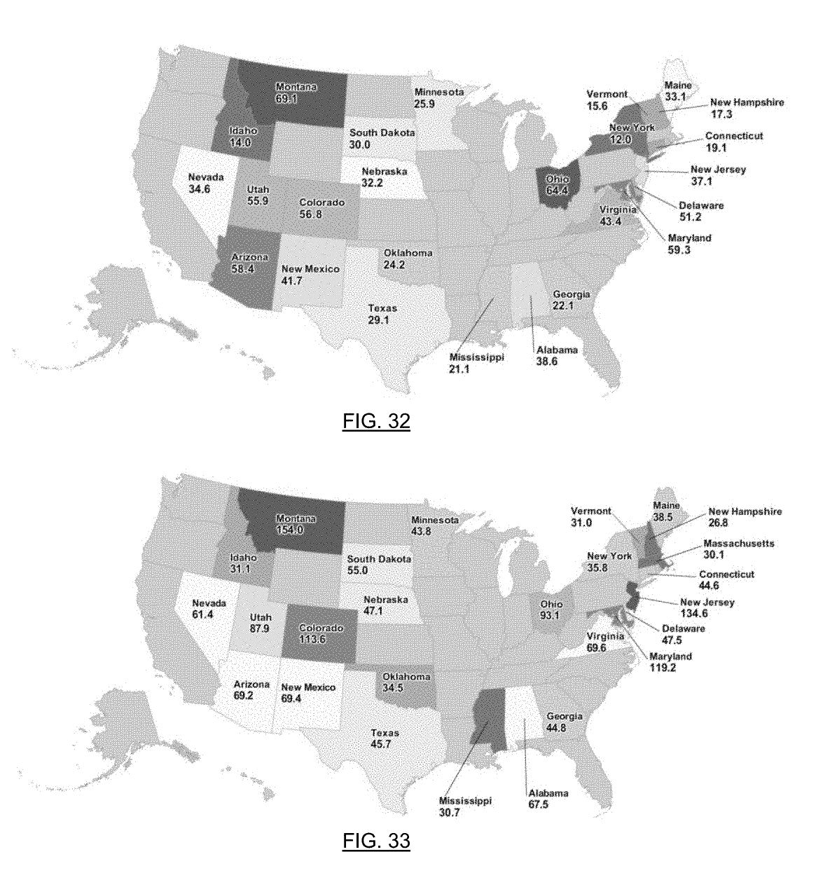

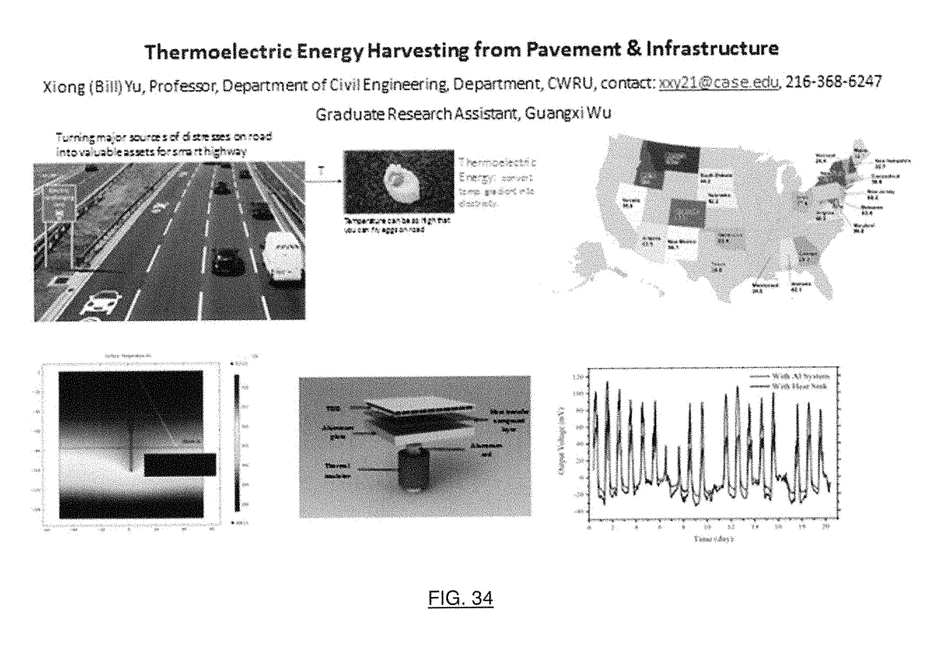

The averaged absolute values of temperature gradients during winter (January) and summer (July) are also plotted in FIGS. 32 and 33. For both months, the comparison among different states roughly maintains the same trend throughout a year. The magnitude of the averaged absolute values of temperature gradients, when compared between the winter and the summer, indicates that the summer causes higher temperature gradients compared to the winter. This means that the TE energy harvesting technology is more effective in summer.

FIGS. 31, 32 and 33 only show the cases where the data completeness is higher than 80%.

Output power of TEM harvesting from pavements heat source.

The averaged absolute values of temperature gradients of multiple states throughout a year were calculated and compared in the previous section. Therefore, the output power densities of the energy harvesting systems can be evaluated, given the efficiency of the TEMs.

Assuming that the TE materials used in the TEMs have figure-of-merit of about 1 at room temperature, the module's figure-of-merit can be as high as 1, if the newly proposed electrically parallel structure is used. Then, the maximum module efficiency can be evaluated using equation (3.1), assuming T_{H}=11° C. and TC=10° C., which are around the annual average climate temperature in Cleveland, Ohio, according to the LTPP database. Calculations show that the maximum power efficiency ηₘₐₓ is around 1%.

If the thermal conductivity of the asphalt concrete layer is assumed to be 1 W/(m·K), assuming the implementation of the TEM does not affect the temperature gradient across the pavement structures, the heat flux flowing through the TEM at Ohio is about 77.4 K/m×1 W/(m·K)=77.4 W/m². Therefore, the output power density of the TEM used to harvest energy from the pavement structure is 77.4 W/m²×1%=0.77 W/m².

When considering a 1 km-long section of highway with a width of 20 m (6 lanes, each lane is 3.7 m wide), the area is about 20,000 m², leading to a significant output power of 15,400 W. If a cost-recovery length is designed to be 10 years, considering the price of electricity to be 10 cents per kW·h, the electric energy produced by the TEM has a profit of about $135,000, meaning $6.75/m². In other words, if the cost to deploy the TEM can be decreased to $1/m², including the TEM fabrication cost, the energy production through this type of application can compete with other energy resources.

Operating Parameters

Further to the above, the leg can be a rod that is utilized as a heat conduction channel to reach a heat sink such as the ground. The length and shape of the rod can be designed based on amount of heat to extract. Thus, the rod can range from about 0.3 to about 3.0 meters, desirably from about 0.5 to about 2 meters, and preferably from about 0.8 to about 1.2 meters.

An aspect of the present invention is to use high efficient heat sources such as black bodies, asphalt or concrete paved roads, parking lot surfaces, dark (such as black) rooftops, and sand exposed to the sun as in an arid or desert environment, and the like. Various metal heat sources can be made of naturally high thermal conductive metals such as iron, steel, aluminum, copper, brass, as well as alloys thereof, or any combination thereof. In other words, the top surface of the TEM can be placed in or beneath the above-noted heat source materials. That is, the above-noted heat sources can be in the form of a cover or an over layer on the TEM. FIG. 5(a) relates to an over layer (1) having High Thermal conductivity to collect heat over a large area (the depth under pavement and thickness depending upon needs and performance). This provides TEM generator to utilize heat over many times larger than its surface area, therefore, saves cost. FIG. 5(b) also relates to an over layer 1 harvester with structure and thermal design optimized to maintain large thermal gradients. Flexible TEM harvester (3) is located inside or on the side/edge of pavement to allow easy installation. The harvester can be designed with electrical parallel structure e or with either p or n material to achieve much higher efficiency than existing system.

The conductive plate of the present invention can generally be made from the same thermally conductive materials as the heat source. Desirable, the conductive plate is a metal such as iron, steel, aluminum, copper, brass, or other metal or any alloy thereof, or any combination thereof that has good thermal conductivity.

The heat transfer compound layer is to reduce the thermal resistance across interface, which can be thermally conductive silicone, thermally conductive epoxy, and other filler material with high thermal conductivity.

The thermal conductive leg desirably can be the same metal such as used for the conductive plate and such metals are hereby fully incorporated.

The heat sink is generally a cool source of material such as the ground, rock, aqueous earth, and the like, or any combination thereof.

### SUMMARY

The proposal of electrically parallel TEMs can potentially stimulate the applications of TE technology, because the implementation process can be extremely simplified if the multilayered electrically parallel TEMs are deployed.

The electrically parallel structure would significantly benefit the fabrication of large-area TEMs.

In-lab experiments showed that the energy harvesting system can periodically power electric load, proving the feasibility of the concept. Outdoor experiments showed that peak output power of the TEM was on the order of mW, which is capable to power some low-energy consumption sensors. These observations present a promising strategy to power sensors used in long-term monitoring systems of civil infrastructures. Another observation is that the output power when the TEM was placed on top of the asphalt concrete sample was more than when the TEM was placed beneath the asphalt concrete sample. In addition, two types of heat exchangers were explored: the aluminum rod inserted deeply into the ground, and the heat sink buried into a shallow layer of the ground. The former heat exchanger was noticed to be less effective. However, the heat exchangers still need to be further verified through outdoor experiments in real pavement environments.

The energy that the TE energy harvesting systems could generate from pavement structures was compared among many states, by calculating the averaged absolute values of temperature gradients with respect to each state, based on LTPP data. The data indicates that the Southern and Northeast coast states have smaller TE energy resources across the pavement than the Western mountainous regions. Also, the energy available in the summer is higher than in the winter. In addition, the power density generated by the TE energy harvesting system is estimated to be 0.77 W/m² in Ohio. When the total cost of deploying one square meter TEM is decreased to 1 dollar, the energy harvesting system can compete with other types of energy resources.

In accordance with the patent statutes, the best mode and preferred embodiment have been set forth; the scope of the invention is not limited thereto, but rather by the scope of the attached claims.

What is claimed is:

1. A thermoelectric-based energy harvesting system, comprising:
a thermoelectric module comprising an upper surface and a lower surface, said upper surface being separated from said lower surface by a “n” type material, or a “p” type material, or both;
said thermal electrical module operatively adapted to be in contact with a heat source;
a thermally conductive plate located beneath said thermoelectric module, said plate capable of transferring heat from said thermoelectric module lower surface to a heat sink via a thermally conductive leg; and
said system being capable of generating electricity.

2. The thermoelectric-based energy harvesting system of claim 1, wherein a minimum temperature difference exists between said upper surface and said lower surface of said thermoelectric module of at least 8° C.

3. The thermoelectric-based energy harvesting system of claim 2, wherein said system is flexible.

4. The thermoelectric-based energy harvesting system of claim 2, wherein said heat source comprises asphalt, concrete, a black body, a parking lot, a roof top, sand, a metal, or any combination thereof.

5. The thermoelectric-based energy harvesting system of claim 4, wherein said heat sink is ground, rock, aqueous earth, or vadose, or any combination thereof.

6. The thermoelectric-based energy harvesting system of claim 5, wherein said thermally conductive plate comprises iron, steel, aluminum, copper, brass, and alloy thereof, or any combination thereof.

7. The thermoelectric-based energy harvesting system of claim 6, wherein said leg is a thermally conductive metal comprising iron, steel, aluminum, copper, brass, and alloy thereof, or any combination thereof.

8. The thermoelectric-based energy harvesting system of claim 7, wherein said thermal conductive plate is steel, aluminum, or copper, or any combination thereof wherein said leg is steel, aluminum, or copper, or any combination thereof.

9. The thermoelectric-based energy harvesting system of claim 7, wherein said temperature differences at least 15° C.

10. The thermoelectric-based energy harvesting system of claim 8, wherein said minimum temperature differences at least 22° C.

11. The thermoelectric-based energy harvesting system of claim 6, including a heat transfer compound layer.

12. The thermoelectric-based energy harvesting system of claim 8, including a heat transfer compound layer located beneath said plate.

13. The thermoelectric-based energy harvesting system of claim 5, wherein said system is adapted to power smart traffic lane indicators, highway sensors, and infrastructure to vehicle communication devices.
